(19) United States
(12) Patent Application Publication
(10) Pub. No.: US 2024/0085779 A1
(43) Pub. Date: Mar. 14, 2024

(54) METHOD AND APPARATUS FOR QUALIFYING A MASK FOR USE IN LITHOGRAPHY

(71) Applicant: Carl Zeiss SMT GmbH, Oberkochen (DE)

(72) Inventors: Renzo Capelli, Heidenheim (DE); Markus Koch, Neu-Ulm (DE); Tim Helbig, Oberkochen (DE); Sandro Hoffmann, Oberkochen (DE); Thomas Niederhausen, Aalen (DE); Grizelda Kersteen, Ulm (DE); Andreas Verch, Oberkochen (DE)

(21) Appl. No.: 18/243,769

(22) Filed: Sep. 8, 2023

(30) Foreign Application Priority Data
Sep. 9, 2022 (DE) 102022209386.0

(51) Int. Cl. G03F 1/44; G03F 1/52; G03F 1/54; G03F 1/84

(52) U.S. Cl. CPC G03F 1/44; G03F 1/52; G03F 1/54; G03F 1/84

(57) ABSTRACT

A method for qualifying a mask for use in lithography is proposed. The method includes the following steps: a provision of an apparatus for qualifying a mask, the apparatus comprising an optical system and an evaluation and control device; a detection of at least one first phase difference of light at the mask by use of the optical system and the evaluation and control device; loading the mask; detecting at least one second phase difference of light at the mask by use of the optical system and the evaluation and control device; and implementing a comparison of the first phase difference with the second phase difference by use of the evaluation and control device.

### CROSS-REFERENCE TO RELATED APPLICATION

The present application claims the priority of the German patent application 10 2022 209 386.0, filed on Sep. 9, 2022. The content of the German patent application is incorporated in the present application by reference.

### TECHNICAL FIELD

The present invention relates to a method for qualifying a mask for use in lithography and to an apparatus for qualifying a mask for use in lithography.

### BACKGROUND

In known lithography methods, masks are used to image structures on wafers in order to produce semiconductor elements. The object here is to image structures that are as small as possible by use of the masks. This places huge demands on the precision of the masks.

The prior art has disclosed methods with which such masks can be examined in advance.

DE 10 2019 215 800 A1 discloses a method for determining an optical phase difference of measurement light at a measurement light wavelength over a surface of a structured object. The phase difference between an absorber structure phase of the measurement light, which is reflected by absorber structures of the object, and a reflector structure phase of the measurement light, which is reflected by reflector structures of the object, is determined as a characteristic that is applicable overall over an object structure to be measured. The method comprises measuring a series of 2-D images of the object in different focal planes in each case, for the purpose of recording a 3-D aerial image of the object using a projection optical unit. Furthermore, the method comprises a reconstruction of an image-side field distribution from the 3-D aerial image, including the amplitude and phase of an electric field of the 3-D aerial image, and the determination of the phase difference from the reconstructed field distribution with the aid of a phase calibration.

Storage effects relating to EUV masks for lithography are described in “Study of EUV reticle storage effects through exposure on EBL2 and NXE,” Proc. of SPIE Vol. 11517 115170Z-1-13.

When a lithography method is performed, the result of the lithography method may be impaired by masks that were modified by storage effects.

### SUMMARY

It is therefore an aspect of the present invention to provide a method and an apparatus for qualifying a mask for use in lithography, which prevent or suppress negative influences of such effects.

Accordingly, a method for qualifying a mask for use in lithography and an apparatus for qualifying a mask for use in lithography are proposed.

By way of example, qualifying the mask may comprise an examination of the mask. As an alternative or in addition, the qualification of the mask may comprise a pretreatment of the mask, for example a pretreatment with light. In a lithography method, the pretreatment can lead to the mask having an effect which is more stable over time and/or more controllable.

The mask can be a photolithographic mask, particularly preferably a photolithographic mask for an extreme ultraviolet (EUV) wavelength range. The mask can be a binary mask, preferably an EUV binary mask, and particularly preferably an EUV phase shifting mask. For example, the mask can be a phase shifting mask, for example an EUV PSM (phase shifting mask). The mask can have a substrate exhibiting little thermal expansion. The mask may comprise a plurality of layers, especially planar layers. On the substrate, the mask may comprise at least one multilayer made of approximately 20 to 80 layers, for example. By way of example, the multilayer may comprise tuned multilayers. By way of example, the multilayer may comprise ruthenium and/or silicon, in particular a RuSi multilayer-layer. As an alternative or in addition, the layers may comprise silicon (Si) and/or molybdenum (Mo), for example. The mask may comprise an absorber structure made of absorbing pattern elements. On the regions of the mask covered by an absorber structure, incident EUV photons can be preferably absorbed or at least not reflected as strongly as in other regions.

The method according to the disclosure includes a plurality of steps. By way of example, the steps can be implemented in succession. In an alternative thereto, one or more steps may temporally overlap at least in part.

The method comprises a provision of an apparatus for qualifying a mask. The apparatus comprises an optical system and an evaluation and control device.

The optical system may comprise an illumination unit, an imaging unit, and a detection unit. The illumination unit may be configured to apply light, especially illumination light, to the mask. The imaging unit may be configured to image, in an image plane, light reflected by the mask. The detection unit may be configured to capture optical image representations of the mask.

The apparatus may comprise at least one housing. By way of example, the optical system may be arranged within the housing, preferably completely within the housing. The evaluation and control device may, at least in part, be arranged within the housing. By way of example, the evaluation and control device may be arranged entirely within the housing. As an alternative thereto, the evaluation and control device may be arranged entirely outside of the housing.

The evaluation and control device may comprise a separate evaluation device and a separate control device, with the two devices possibly being interconnected by use of an interface. As an alternative thereto, the evaluation and control device may be designed as one apparatus. The evaluation and control device may preferably comprise a data processing apparatus. By way of example, the evaluation and control device can be operated by a person by use of an interface. This interface device can be a keyboard or a touchpad.

The method comprises a detection of at least one first phase difference of light at the mask by use of the optical system and the evaluation and control device. The light can be illumination light from the illumination unit in particular. The first phase difference can be a phase difference arising between at least one first light beam and at least one second light beam as a result of interaction with the mask. The interaction can be a transmission and/or a reflection at the mask.

By way of example, the first phase difference may arise as a result of the fact that the first light beam is reflected at a first layer of the mask and the second light beam is reflected at a second layer of the mask, in particular following at least one transmission of the first light beam through at least one layer of the mask and/or at least one transmission of the second light beam through at least one layer of the mask.

Preferably, the first light beam and the second light beam may have the same phase prior to the interaction with the mask. An angle of incidence of the first light beam on the mask can preferably be identical to an angle of incidence of the second light beam on the mask. As an alternative thereto, the first light beam and the second light beam may already have a phase difference with respect to one another and/or different angles of incidence prior to the interaction with the mask.

The detection unit may be configured to convert an interference of the first light beam with the second light beam or with a reference light beam into digital data. The evaluation and control device may be configured to calculate the first phase difference from the digital data.

In particular, the determination of the first phase difference may be implementable as described in DE 10 2019 215 800 A1.

When the first phase difference is detected, it is possible to choose a light dose of the light to be so low that this cannot generate any effects on the first phase difference.

The method according to the disclosure furthermore comprises loading of the mask. Loading of the mask can be designed in such a way that loading brings about a change in the refractive index and/or in a topology of at least one portion of the mask.

The loading of the mask may be selected from a group comprising an input of energy into the mask, an application of electromagnetic radiation to at least a partial area of the mask during at least one time interval, an input of heat into the mask, a storage time of the mask in a device for storing the mask, a storage time in the apparatus for qualifying a mask, a storage time of the mask in vacuo, an application of at least one gas to the mask, a contamination of the mask, an application of a particle beam to the mask, and a repair process on the mask.

By way of example, the partial area can be a rectangular partial area. By way of example, the electromagnetic radiation can be EUV radiation and/or radiation at a different wavelength, for example visible light. By way of example, the loading can be preconditioning or act as such. The loading can be stamping, for example triggered by physical and/or chemical changes.

The gas can be a pure gas. As an alternative thereto, the gas can be a gas mixture. The gas mixture may contain at least one gas selected from the group comprising helium, hydrogen, oxygen, nitrogen, neon, argon, krypton, and xenon. Loading the mask may comprise an application of a liquid, for example water. As an alternative thereto, loading may be an application of moisture to the mask, for example by bringing the mask into contact with air or water vapor.

By way of example, electromagnetic radiation, especially illumination light, may be applied to the mask during the step of loading the mask. As an alternative or in addition thereto, there can be an input of heat into the mask, for example by thermal conduction or thermal radiation, for example by use of electromagnetic radiation, during the loading step.

By way of example, loading may comprise a correction method for the mask and/or a repair method for the mask and/or a cleaning method for the mask.

By way of example, the mask may be loaded while said mask is transported and/or while said mask is used in a lithography method, for example in a lithography apparatus.

The method further comprises a detection of at least one second phase difference of light at the mask by use of the optical system and the evaluation and control device. The second phase difference can be a phase difference arising between at least one third light beam and at least one fourth light beam as a result of interaction with the mask. The interaction can be a transmission and/or a reflection at the mask. By way of example, the second phase difference may arise as a result of the fact that the third light beam, for example, is reflected at the first layer of the mask and the fourth light beam is reflected at the second layer of the mask, in particular following at least one transmission of the third light beam through at least one layer of the mask and/or at least one transmission of the fourth light beam through at least one layer of the mask. Preferably, the third light beam and the fourth light beam may have the same phase prior to the interaction with the mask. An angle of incidence of the third light beam on the mask can preferably be identical to an angle of incidence of the fourth light beam on the mask. As an alternative thereto, the third light beam and the fourth light beam may already have a phase difference with respect to one another and/or have different angles of incidence prior to the interaction with the mask. The detection unit may be configured to convert an interference of the third light beam with the fourth light beam into digital data. The evaluation and control device may be configured to calculate the second phase difference from the digital data. By way of example, the first light beam may correspond to the third light beam and the second light beam may correspond to the fourth light beam, especially in respect of an angle with respect to the mask and in respect of a local point of incidence on the mask.

In particular, the determination of the second phase difference may be implementable as described in DE 10 2019 215 800 A1. By way of example, the first phase difference and/or the second phase difference may be detected by use of a phase metrology method. The method can comprise a wavefront analysis, for example.

The determination of the second phase difference can be implemented like the determination of the first phase difference. Preferably, the first light beam and the third light beam may have identical angles of incidence and points of incidence on the mask. Additionally, the second light beam and the fourth light beam may preferably have identical angles of incidence and points of incidence on the mask.

The apparatus may comprise a holder for receiving the mask. By way of example, the mask may be held by the holder while the first phase difference and the second phase difference are detected. By way of example, the mask might not be held by the holder during loading. As an alternative thereto, the mask may also be held by the holder during loading.

The method comprises an implementation of a comparison of the first phase difference with the second phase difference by use of the evaluation and control device. By way of example, the first phase difference can be compared with the second phase difference by way of a computing operation. The comparison of the first phase difference with the second phase difference may comprise a determination of a difference between the first phase difference and the second phase difference by use of the evaluation and control device. As an alternative or in addition, the comparison of the first phase difference with the second phase difference may comprise a division between the first phase difference and the second phase difference by use of the evaluation and control device. By way of example, a plurality of first phase differences and/or a plurality of second phase differences may be used for the comparison, for example comprising at least one averaging step. By way of example, a difference between a fifth second phase difference and a mean value of the first phase difference and the first four phase differences may be formed for the comparison. By way of example, the method may comprise a comparison of a second phase difference with a mean value of preceding phase differences, for example of the five previously measured phase differences.

By way of example, the evaluation and control device may comprise an output apparatus, for example a display and/or a monitor. A result of the comparison may be presented graphically, for example by use of the display and/or monitor. This can facilitate an operation of the apparatus by a person.

By way of example, the mask may comprise an absorber structure and a reflector structure. The absorber structure may have a height of 1 nm to 1000 nm, preferably 20 nm to 150 nm, and particularly preferably 40 nm to 100 nm. When detecting the at least one first phase difference and the at least one second phase difference, it is possible in each case to detect at least one phase difference between an absorber light beam reflected at the absorber structure and a reflector light beam reflected at the reflector structure, for example at a multilayer. The first light beam and the third light beam can be absorber light beams and the second light beam and the fourth light beam can be reflector light beams. As a result, the method according to the disclosure can be used to analyze whether there has been a physical change to the absorber structure and/or the reflector structure during the loading, especially to the effect of this possibly leading to changes in the result when the mask is used in a lithography method, for example leading to defects, especially leading to a reduction in precision.

The mask may preferably comprise periodic structures, in particular periodic reflector structures. This can facilitate the detection of first phase differences and second phase differences. A spacing between the periodic structures can be 100 nm to 2000 nm, preferably 300 nm to 1800 nm, and particularly preferably 400 nm to 1600 nm. Preferably, periodic structures may be located in all regions of the mask that are intended to be examined by use of the method according to the disclosure.

One or more of the steps may be repeated during the method. By way of example, the detection of the first phase difference and/or the loading of the mask and/or the detection of the second phase difference and/or the implementation of the comparison can be repeated, in particular multiple times.

By way of example, the detection of the first phase difference, the loading of the mask, and the detection of the second phase difference can be carried out in the specified sequence, for example also in partly overlapping fashion. The aforementioned steps can be repeated one or more times in sequence, especially before the comparison is implemented.

As an alternative thereto, the detection of the first phase difference, the loading of the mask, the detection of the second phase difference, and also the implementation of the comparison could be implemented in the specified sequence and could be repeated sequentially.

By way of example, one or more steps can be repeated for different fields of view of a mask. By way of example, at least one first phase difference and one second phase difference can be determined in each case for more than 5 fields of view per hour, preferably for more than 10 fields of view per hour, and particularly preferably for 15 to 18 fields of view per hour. By way of example, a plurality of first phase differences and/or a plurality of second phase differences can each be detected simultaneously at different locations on the mask in the case of one field of view of the mask.

The aforementioned steps may each temporally overlap at least in part. By way of example, the mask can be loaded continuously while detecting the first phase difference and while detecting the second phase difference, in particular loaded from the start of the detection of the first phase difference until the end of the detection of the second phase difference, for example also loaded until the comparison is implemented.

By way of example, the mask is loaded between the start of the detection of the first phase difference and the start of the detection of the second phase difference. In particular, the mask can be loaded between each start of the detection of the first phase difference and each start of the detection of the second phase difference. By way of example, the start of the detection of the first phase difference can be the time of interaction between the first light beam and the mask. By way of example, the start of the detection of the second phase difference can be the time of interaction between the third light beam and the mask.

The loading can be designed in such a way that a difference between the first phase difference and the second phase difference of between 0.01π and 1.99π, preferably of between 0.7π and 1.3π, and particularly preferably of between 0.9π and 1.1π arises, where π is the mathematical constant. A phase difference of π can be particularly advantageous for use in lithography. By way of example, a contrast can be maximal in this case.

The first phase difference and the second phase difference may be determined by physical properties of parts of the mask, especially by geometric extents and refractive indices. Under loading, geometric extents of the mask and/or refractive indices of the mask may change to such an extent that this yields a measurable difference between the first phase difference and the second phase difference.

During the method, the mask can be at least loaded up to a threshold value. The threshold value may be a characteristic for the loading, above which a measurable difference between the first phase difference and the second phase difference arises by use of the method according to the disclosure. The threshold value can be a value of a physical variable, for example selected from a group comprising a time, a temperature, a luminous power and a gas pressure. The threshold value may characterize a loading above which the mask physically and/or chemically changes to such an extent by the loading that this can be detected by use of the method according to the disclosure. By way of example, the threshold value can be a minimum energy input for obtaining a difference that is measurable by the method between the first phase difference and the second phase difference. The threshold value can be implemented by use of a plurality of detections of first phase differences and/or a plurality of detections of second phase differences, for example in the case of repeated and/or increasing loading.

By way of example, the threshold value can be from 5*10⁻¹⁰ J/μm² to 5*10⁻⁷ J/μm². In the case of an illumination spot of the apparatus of 14 μm×14 μm for example, the threshold value can be at an energy input of 1*10⁻⁷ J to 1*10⁻⁴ J, preferably 1*10⁻⁵ J to 5*10⁻⁵, and particularly preferably 1.8*10⁻⁵ J to 2*10⁻⁵ J.

The threshold value can be determined by use of the evaluation and control device. The evaluation and control device can determine the threshold value by determining a physical variable of the loading, above which a difference that is measurable by use of the method arises between the first phase difference and the second phase difference. In this way, it might be possible for example to determine a minimum heat input and/or a minimum application of electromagnetic radiation or particle radiation, above which the latter has an influence on the result of the lithography on the wafer during a lithography method. By way of example, the heat input can be an at least partial change in the temperature of the mask. By determining the threshold value, the behavior of the mask can be optimally analyzed for a subsequent use in a lithography method and/or the mask can be pretreated in such a way that the latter is less sensitive to loads within a use in a lithography method.

The mask can be at least loaded up to a saturation value. The saturation value can be a characteristic of the loading, above which there is no further change in the second phase difference in the case of further loading. The saturation value can be a value of a physical variable.

The saturation value can be a loading above which the mask changes physically and/or chemically in such a way that, in the case of further loading, no further difference between a first phase difference and a second phase difference can be detected by use of the method according to the disclosure. By way of example, the saturation value can be a minimum energy input for no longer obtaining, in the case of further loading, any further difference that is measurable by the method between the first phase difference and the second phase difference.

By way of example, the saturation value can be determined by use of the evaluation and control device, in particular by evaluating a curve of a plurality of first phase differences and/or second phase differences captured successively in time, with the mask being loaded between the detections or there being continuous loading.

By way of example, a relaxation time can be determined by use of the evaluation and control device. The relaxation time can be a minimum duration following at least partially reversible loading, after which a difference between a first phase difference and a second phase difference no longer changes, especially without further loading, and particularly preferably without further loading above the threshold value.

By way of example, the mask can be exposed to the loading by use of the optical system, in particular by illumination light. As an alternative thereto, the mask can be exposed to loading not generated by the optical system, for example by way of a cleaning method, especially in another apparatus.

By way of example, the mask can be exposed to the loading by use of a device for storing the mask. The device for storing the mask may be a part of the apparatus according to the disclosure. In this case, loading may be implemented for example by an application of air and/or another gas mixture or a gas.

A cause for a difference between the first phase difference and the second phase difference can be determined by use of the evaluation and control device from the comparison of the first phase difference with the second phase difference. In particular, a cause for the difference can be determined by use of the evaluation and control device from the difference between the first phase difference and the second phase difference. The cause may be selected from a group comprising an input of energy into the mask, an application of electromagnetic radiation to at least a partial area of the mask during at least one time interval, an input of heat into the mask, a storage time of the mask in the device for storing the mask, a storage time in the apparatus for qualifying a mask, a storage time of the mask in vacuo, an application of at least one gas to the mask, a contamination of the mask, an application of a particle beam to the mask, and a repair process on the mask.

By way of example, the cause can be determined by evaluating the level of the difference between the first phase difference and the second phase difference and/or from the threshold value and/or from the saturation value and/or from the relaxation time and/or from a time between the detection of the first phase difference and a detection of a second phase difference.

If the loading is implemented by way of a use in a lithography method, then the method according to the disclosure can for example be used to deduce an error during the lithography method, for example an inadvertent application of a gas and/or an inadvertent energy input. For example, this can implement an error analysis in respect of a lithography method and/or an apparatus for lithography and/or an apparatus according to the disclosure. By way of example, a contamination of the mask and/or a compaction of the mask may arise due to the loading. This may in each case lead to a characteristic change in the difference between the first phase difference and the second phase difference and/or to a characteristic relaxation time, especially when taking account of a time between the detection of the first phase difference and the detection of a second phase difference. By way of example, the cause may be rectified in a further step, for example by cleaning the mask. This may improve a result of a lithography method implemented with the mask.

At least one first two-dimensional image representation may be captured for the purpose of detecting the at least one first phase difference by use of the apparatus for qualifying the mask. At least one second two-dimensional image representation may be captured for the purpose of detecting the at least one second phase difference. The first two-dimensional image representation and the second two-dimensional image representation can preferably be image representations of the mask. The first two-dimensional image representation and the second two-dimensional image representation can be what are known as aerial images. The first two-dimensional image representation and the second two-dimensional image representation can preferably image both absorber structures and reflective structures of the mask, preferably a periodic structure made of absorber structure and reflector structure.

By way of example, the mask may comprise an absorber structure, with a substrate and a multilayer layer being able to be arranged parallel to the absorber structure and with the multilayer layer being able to be located between the substrate and absorber structure. Alternatively, no multilayer layer may be parallel to an absorber structure. As an alternative or in addition, the mask may comprise a structure without a multilayer layer and without an absorber layer. As an alternative or in addition, the mask may comprise a multilayer layer on a substrate without an absorber layer. The multilayer may have a higher reflectivity than an absorber layer and/or the substrate.

A series of first two-dimensional image representations of the mask, with these possibly being captured in different focal planes at least in part, can be captured for the purpose of detecting the at least one first phase difference by use of the apparatus for qualifying the mask. The series of first two-dimensional image representations of the mask may be a first focal stack. The series of first two-dimensional image representations may for example comprise at least two, preferably at least three, and particularly preferably at least ten image representations in different focal planes.

A series of second two-dimensional image representations of the mask, with these possibly being captured in different focal planes at least in part, can be captured for the purpose of detecting the at least one second phase difference by use of the apparatus for qualifying the mask. The series of second two-dimensional image representations of the mask may be a second focal stack. The series of second two-dimensional image representations may for example comprise at least two, preferably at least three, and particularly preferably at least ten image representations in different focal planes.

A first three-dimensional image can be created from the series of first two-dimensional image representations. The first phase difference can be calculated from the first three-dimensional image by use of the evaluation and control device. A second three-dimensional image can be created from the series of second two-dimensional image representations. The second phase difference can be calculated from the second three-dimensional image by use of the evaluation and control device. By way of example, a comparison with a reconstructed field distribution can be implemented, for example comprising an iterative method, during the detection of the first phase difference and/or the detection of the second phase difference. In addition to the first phase difference and to the second difference, it is for example possible in each case to capture a first amplitude and a second amplitude.

A two-dimensional distribution of a plurality of first phase differences can be determined from the series of first two-dimensional image representations of the mask. A two-dimensional distribution of a plurality of second phase differences can be determined from the series of second two-dimensional image representations of the mask. A difference distribution between the first phase difference and the second phase difference can be determined by use of the evaluation and control device from the two-dimensional distribution of a plurality of first phase differences and the two-dimensional distribution of a plurality of second phase differences.

As an alternative thereto, a difference distribution between the first phase difference and the second phase difference can be determined directly from the series of first two-dimensional image representations and the series of second two-dimensional image representations of the mask.

By way of example, the difference distribution between the first phase difference and the second phase difference can be a two-dimensional graphical representation. By way of example, an area of the mask exposed to an application of electromagnetic radiation as loading can be determined by use of the graphical representation of the difference distribution. By way of example, the difference distribution can be output as a graphical representation for a user, with the result that they can identify for example a region of the mask which was subjected to loading.

By way of example, a control signal for the apparatus for qualifying the mask can be generated within the method. The control signal can be created by means of the comparison. By way of example, the evaluation and control device can be used to determine whether the threshold value and/or the saturation value was obtained by the loading. By way of example, a control signal can be output if the threshold value and/or the saturation value has been reached, for example to stop a repetition of a sequence of method steps and/or to increase or reduce loading. In this way, a mask can for example be pretreated for an optimal use in a lithography method.

By way of example, the mask can be at least partially exposed prior to a detection of the first phase difference and/or the second phase difference, in particular exposed in such a way that the mask is considered pretreated and supplies a reproducible result during a detection of a phase difference.

The light can have a wavelength between 1 nm and 250 nm, in particular between 10 nm and 100 nm, and preferably between 13 nm and 14 nm. The apparatus according to the disclosure may comprise reflective optical elements. This can achieve functionality in the case of wavelengths in the EUV range.

The light can be pulsed light with a pulse duration of between 0.1 femtoseconds and 400 nanoseconds, preferably between 50 femtoseconds and 100 nanoseconds, and particularly preferably between 25 and 35 nanoseconds. The pulse duration can be an interval which starts when 10% of the maximum power is reached and which ends when 10% of the maximum power is undershot. A decay rate τ can for example be less than 1/repetition rate, and particularly preferably less than 0.1/repetition rate. The light at the mask can have an energy dose of 1 mJ/cm² to 1000 mJ/cm², preferably more than 100 mJ/cm², and particularly preferably more than 200. The maximum temperature can be less than 100° C., preferably less than 80° C., and preferably 77° C. By way of example, the pulse duration may be constant during the method. As an alternative thereto, it is possible to vary the pulse duration during the method, for example by at least +/−100%, preferably by at least +/−50%, and particularly preferably by at least +/−25%. By way of example, an energy input per pulse may be constant during the method. As an alternative thereto, it is possible to vary the energy input per pulse during the method, for example by at least +/−100%, preferably by at least +/−50%, and particularly preferably by at least +/−25%. By way of example, a pretreatment may be more effective and/or efficient and/or a saturation may be attained earlier in the case of higher energy inputs per pulse. Damage to the mask might be prevented in the case of reduced energy inputs per pulse. To attain saturation, an aperture of the apparatus may for example be increased and/or a pulse duration may be lengthened accordingly up until saturation. By way of example, EUV light may be applied to the mask prior to the detection of the first phase difference and/or the second phase difference, in order to attain saturation.

In a further aspect, an apparatus for qualifying a mask for use in lithography is proposed. The apparatus can be configured to carry out the method according to the invention. The optical system and the evaluation and control device of the apparatus according to the disclosure are configured to detect a first phase difference of light at the mask. The apparatus is configured to expose the mask to loading. The optical system and the evaluation and control device are configured to detect a second phase difference of light at the mask after loading. The evaluation and control device is configured to implement a comparison of the first phase difference with the second phase difference.

The apparatus may comprise a device for storing the mask. The device for storing the mask may be configured to apply at least one gas to the mask. The gas may be selected from a group comprising oxygen, nitrogen, hydrogen, and helium. The optical system may comprise an illumination unit, an imaging unit, and a detection unit. The illumination unit may be configured to apply light to the mask. The illumination unit may comprise an EUV light source. The imaging unit may be configured to image, in an image plane, light reflected by the mask. The detection unit may be configured to capture a first two-dimensional image representation of the mask and a second two-dimensional image representation of the mask. The evaluation and control device may be configured to determine the first phase difference by use of the first two-dimensional image representation. The evaluation and control device may be configured to determine the second phase difference by use of the second two-dimensional image representation.

The optical system may comprise a drive. The drive may be configured to vary a focal position. By way of example, the first focus stack and/or the second focus stack may be generated by use of the drive.

By way of example, the method according to the disclosure may be carried out in succession on at least two apparatuses according to the disclosure. Defects of the apparatuses, for example a vacuum leak and/or an inadvertent application of electromagnetic radiation and/or contamination, can be deduced by use of a comparison between the measurement results from the different apparatuses. This allows qualification of one of the two apparatuses.

By way of example, the method according to the disclosure can be carried out repeatedly, for example at an interval of at least one year, preferably 7 months, and particularly preferably 3 weeks. By way of example, defects of one apparatus, for example a vacuum leak and/or an inadvertent application of electromagnetic radiation and/or contamination, can be deduced by use of a temporal repetition at one or more apparatuses. As a result, the apparatus and/or the mask can be qualified.

The apparatus according to the disclosure and the method according to the disclosure have various advantages, at least in exemplary embodiments. By use of the novel method and the novel apparatus, it is possible to determine and/or analyze changes of a mask under loading.

By way of example, changes of multilayers and/or absorber structures of the mask generated by EUV light can be detected and analyzed by use of the method according to the disclosure and the apparatus according to the disclosure.

By way of example, the cause of loading and/or a change in the mask can be analyzed. As an alternative or in addition, there can be a preconditioning of the mask, for example up to a threshold value and/or a saturation value. The reproducibility of the lithography is very important in the case of a lithography method. A reproducibility of a lithography process can be increased by use of the method according to the disclosure, for example by preconditioning the mask and/or analyzing the behavior of the mask under loading. As a result, a better result can be obtained when the mask is used in a lithography method, for example as a result of a higher contrast. As an alternative or in addition, a reliable calibration can be carried out by use of the method according to the disclosure and the apparatus according to the disclosure, especially in view of an absorber edge. In particular, it is possible to determine a sensitivity of phase differences in respect of changes in the absorber structure, for example in order to prevent or suppress phase oscillations. In particular, the production of rejects can be suppressed or prevented within the scope of a lithography method. A throughput can be increased by use of the method according to the disclosure and the apparatus according to the disclosure, especially when the mask is used in a lithography method.

Preferably, the method can be designed so that an accuracy of for example up to 5°, preferably up to 2.5°, can be achieved. The method can be designed so that a reproducibility of up to 0.7°, in particular up to 0.05°, can be achieved.

It goes without saying that the aforementioned features and those explained hereinbelow can be used not only in the combination specified in each case but also in other combinations or on their own, without departing from the scope of the present disclosure.

### BRIEF DESCRIPTION OF DRAWINGS

Exemplary embodiments of the disclosure are illustrated in the drawings and will be explained in more detail with reference to the following description. In the drawings:

FIG. 1 shows a schematic illustration of a first exemplary embodiment of a method according to the disclosure;

FIG. 2A shows a schematic illustration of a mask for use in a second exemplary embodiment of the method according to the disclosure;

FIG. 2B shows a schematic illustration of a layer structure of a mask for use in the second exemplary embodiment of the method according to the disclosure;

FIG. 2C shows an illustration of a two-dimensional distribution of a plurality of first phase differences in accordance with the second exemplary embodiment of the method according to the disclosure;

FIG. 2D shows an illustration of a two-dimensional distribution of a plurality of second phase differences in accordance with the second exemplary embodiment of the method according to the disclosure;

FIG. 2E shows a difference distribution in accordance with the second exemplary embodiment of the method according to the disclosure;

FIG. 3 shows a schematic illustration of a third exemplary embodiment of a method according to the disclosure;

FIG. 4 shows a schematic illustration of a fourth exemplary embodiment of a method according to the disclosure;

FIG. 5 shows a schematic illustration of a fifth exemplary embodiment of a method according to the disclosure;

FIG. 6 shows a schematic illustration of a sixth exemplary embodiment of a method according to the disclosure;

FIG. 7 shows a schematic illustration of a seventh exemplary embodiment of a method according to the disclosure;

FIG. 8A shows an illustration of a change of a temperature of a part of the mask over time during an eighth exemplary embodiment of a method according to the disclosure;

FIG. 8B shows an illustration of a possible change of the difference between the first phase difference and the second phase difference over time during the eighth exemplary embodiment of a method according to the disclosure;

FIG. 8C shows an illustration of a possible change of the difference between the first phase difference and the second phase difference over time during a ninth exemplary embodiment of a method according to the disclosure;

FIG. 9 shows illustrations of changes of the difference between the first phase difference and the second phase difference in further exemplary embodiments of the method according to the disclosure;

FIG. 10 shows a schematic illustration of a first exemplary embodiment of an apparatus according to the disclosure; and

FIG. 11 shows a schematic illustration of a second exemplary embodiment of an apparatus according to the disclosure.

### DETAILED DESCRIPTION

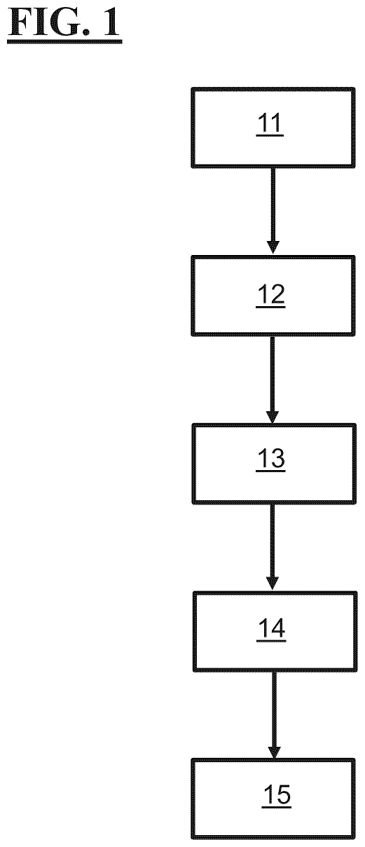

FIG. 1 shows a first exemplary embodiment of a method according to the disclosure for qualifying a mask 20 for use in lithography. The method comprises a provision 11 of an apparatus 22 for qualifying a mask 20.

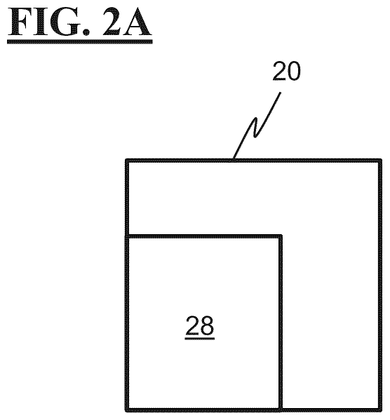

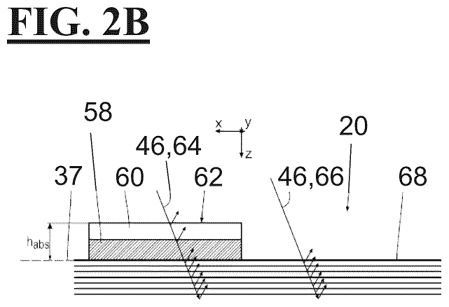

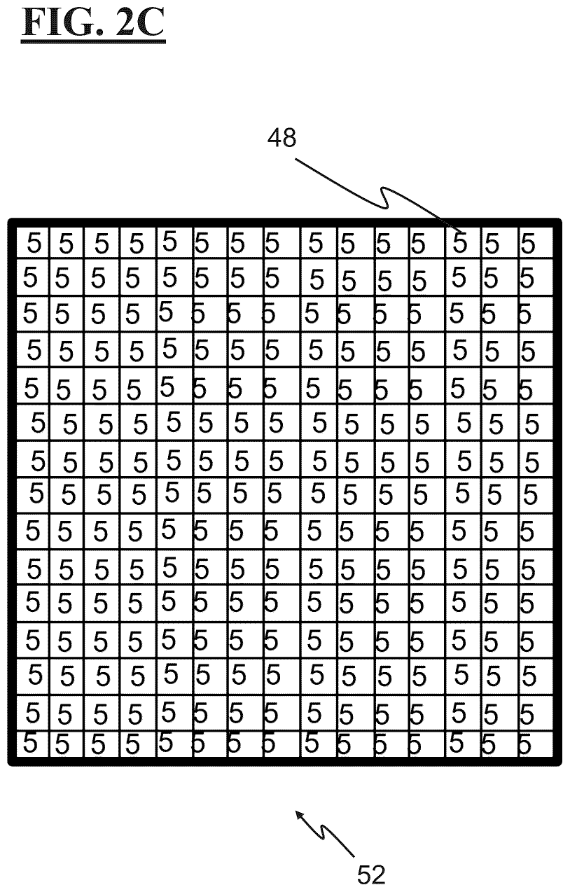

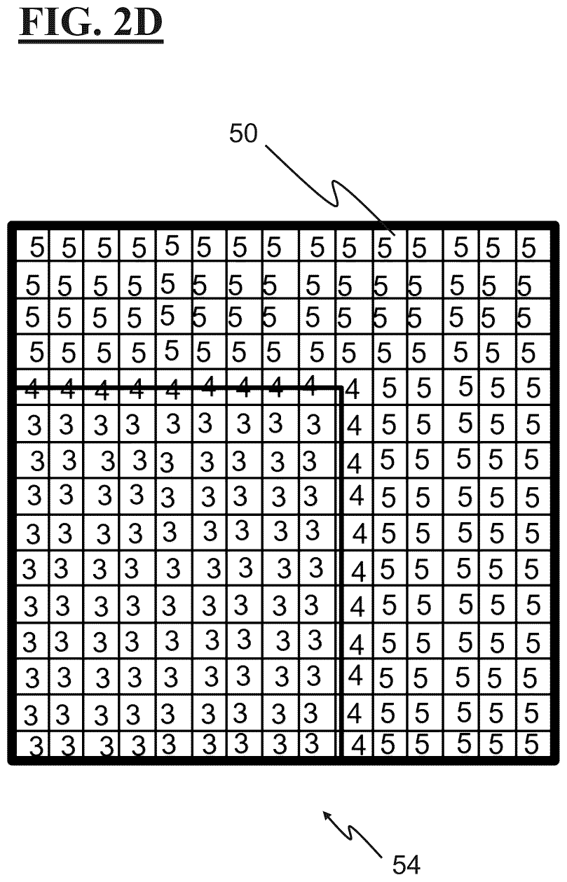

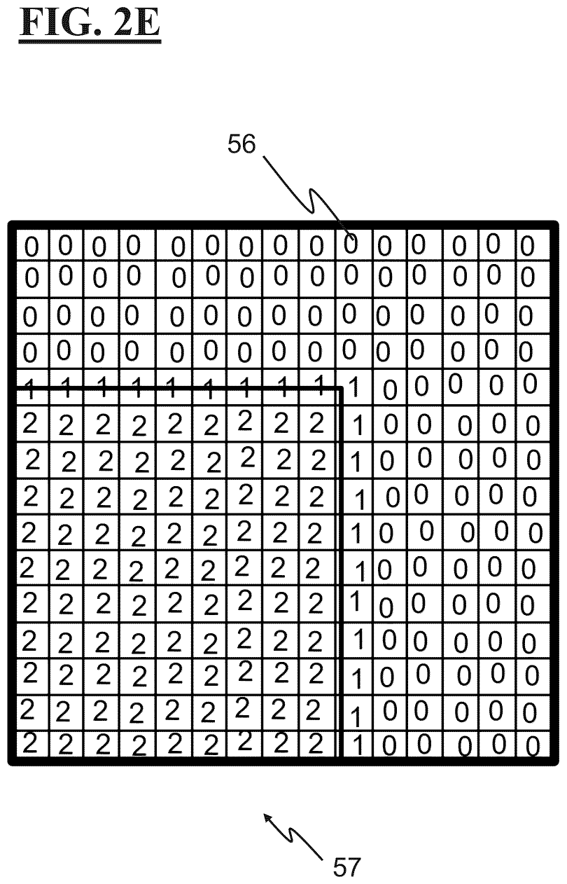

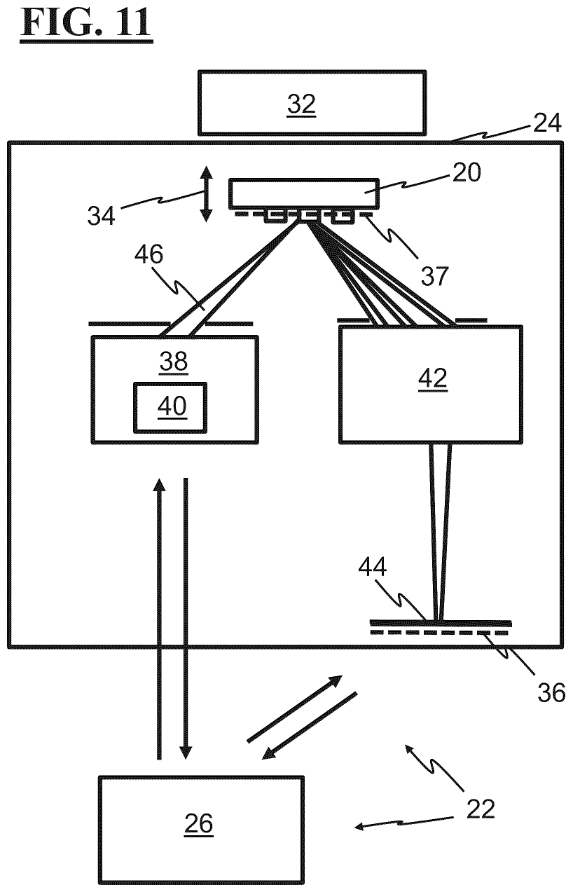

By way of example, the apparatus 22 can be an apparatus 22 according to the disclosure and in accordance with FIG. 10 or FIG. 11. The exemplary embodiments of the apparatuses 22 according to the disclosure and according to FIGS. 10 and 11 comprise an optical system 24 and an evaluation and control device 26. The optical system 24 and the evaluation and control device 26 are configured to detect a first phase difference 48 (FIG. 2C) of light 46 at the mask 20. The apparatus 22 is configured to expose the mask 20 to loading 13. The optical system 24 and the evaluation and control device 26 are configured to detect a second phase difference 50 (FIG. 2D) of light 46 at the mask 20 after loading 13. The evaluation and control device 26 is configured to implement a comparison 15 of the first phase difference 48 with the second phase difference 50. The optical system 24 may comprise an illumination unit 38, an imaging unit 42, and a detection unit 44. The illumination unit 38 may be configured to apply light 46 to the mask 20. The illumination unit 38 can include, e.g., one or more lenses, and/or one or more light reflecting surfaces (e.g., mirrors). The imaging unit 42 may be configured to image, in an image plane 36, light 46 reflected by the mask 20. The imaging unit 42 can include, e.g., one or more lenses, and/or one or more light reflecting surfaces (e.g., mirrors). The detection unit 44 may be configured to capture a first two-dimensional image representation of the mask 20 and a second two-dimensional image representation of the mask 20. The detection unit 44 can include, e.g., one or more charge-coupled device (CCD) sensors and/or one or more complementary metal-oxide semiconductor (CMOS) sensors. The optical system 24 may comprise a drive 34. The drive 34 can include, e.g., one or more motors. The drive 34 may be configured to vary a focal position. The evaluation and control device 26 may be configured to determine the first phase difference 48 by use of the first two-dimensional image representation. The evaluation and control device 26 may be configured to determine the second phase difference 50 by use of the second two-dimensional image representation.

In contrast to the apparatus 22 according to FIG. 10, the apparatus 22 according to FIG. 11 comprises a device 32 for storing the mask 20. Otherwise, the exemplary embodiments according to FIG. 10 and FIG. 11 have identical designs. The mask 20 can be exposed to the loading 13 by use of a device 32 for storing the mask 20. The device 32 for storing the mask 20 may be configured to apply at least one gas to the mask 20. The gas may be selected from a group comprising oxygen, nitrogen, hydrogen, and helium. By way of example, local changes in properties of the mask 20, which were caused by EUV irradiation in surroundings with helium and/or hydrogen, can be detected and analyzed by use of the method according to the disclosure. The device 32 for storing the mask 20 may be connected directly to a measurement chamber of the apparatus 22. By way of example, the apparatus 22 may comprise a plurality of devices 32 for storing one or more masks 20. The device 32 for storing the mask 20 may be configured to attain a saturation of loading 13 by vacuum effects. By use of one or more devices 32 for storing one or more masks 20, it is possible, for example, to measure a plurality of masks 20 simultaneously. This can save time and/or increase effectivity and/or reduce costs. The evaluation and control device 26 is configured to implement a comparison 15 of the first phase difference 48 with the second phase difference 50.

The optical system 24 of the exemplary embodiments according to FIG. 10 and FIG. 11 may comprise an illumination unit 38, an imaging unit 42, and a detection unit 44. The illumination unit 38 may be configured to apply light 46 to the mask 20. The imaging unit 42 may be configured to image, in an image plane 36, light 46 reflected by the mask 20. The detection unit 44 may be configured to capture a first two-dimensional image representation of the mask 20 and a second two-dimensional image representation of the mask 20. The evaluation and control device 26 may be configured to determine the first phase difference 48 by use of the first two-dimensional image representation. The evaluation and control device 26 may be configured to determine the second phase difference 50 by use of the second two-dimensional image representation. The illumination unit 38 may comprise an EUV light source 40. The light 46 can have a wavelength between 1 nm and 250 nm, in particular between 10 nm and 100 nm, and preferably between 13 nm and 14 nm. The light 46 can be pulsed light with a pulse duration of between 0.1 femtoseconds and 400 nanoseconds, preferably between 50 nanoseconds and 100 nanoseconds, and particularly preferably between 25 and 35 nanoseconds. The pulse duration can be an interval which starts when 10% of the maximum power is reached and which ends when 10% of the maximum power is undershot.

The method according to FIG. 1 comprises a detection 12 of at least one first phase difference 48 of light 46 at the mask 20 by use of the optical system 24 and the evaluation and control device 26, a loading 13 of the mask 20, a detection 14 of at least one second phase difference 50 of light 46 at the mask 20 by use of the optical system 24 and the evaluation and control device 26, and an implementation of a comparison 15 of the first phase difference 48 with the second phase difference 50 by use of the evaluation and control device 26, especially in the aforementioned sequence.

The loading 13 can be selected from a group comprising an input of energy into the mask 20, an application of electromagnetic radiation to at least a partial area 28 of the mask 20 during at least one time interval 30, an input of heat into the mask 20, a storage time 31 of the mask 20 in the device 32 for storing the mask 20, a storage time 31 in the apparatus 22 for qualifying a mask 20, a storage time 31 of the mask 20 in vacuo, an application of at least one gas to the mask 20, a contamination of the mask 20, an application of a particle beam to the mask 20, and a repair process on the mask 20.

The mask 20 can be designed as depicted in FIG. 2A and FIG. 2B. As depicted in FIG. 2B, the mask 20 may comprise an absorber structure 62 and a reflector structure 68. The absorber structure 62 may preferably extend only over a part of a lateral extent of the mask 20. The reflector structure 68 may preferably have a greater lateral extent than the absorber structure 62. The reflector structure 68 may be at least partially covered by the absorber structure 62. The absorber structure 62 may have a height h_{abs}. By way of example, the height may vary by no more than ±10%, preferably by no more than ±5%, and particularly preferably by no more than ±1% over the mask 20. The height of the absorber structure 62 h_{abs} may be 1 nm to 1000 nm, preferably 30 nm to 100 nm, and particularly preferably 40 nm to 70 nm. The absorber height can particularly preferably be less than 70 nm. A height of less than 70 nm can suppress 3-D effects and hence increase an accuracy. By way of example, the absorber structure 62 may comprise a first absorber layer 58 and a second absorber layer 60. The absorber structure 62 may be arranged above an object plane 37 and the reflector structure 68 may be arranged below the object plane 37. The object plane 37 can be the plane in which the absorber structure 62 and the reflector structure 68 are in contact.

When detecting 12 the at least one first phase difference 48 and the at least one second phase difference 50, it is possible in each case to detect at least one phase difference between an absorber light beam 64 reflected at the absorber structure 62 and a reflector light beam 66 reflected at the reflector structure 68.

By way of example, a control signal can be generated within the scope of the method according to the invention for the apparatus 22 for qualifying the mask 20, the control signal being able to be created by means of the comparison 15.

At least one first two-dimensional image representation may be captured for the purpose of detecting 12 the at least one first phase difference 48 by use of the apparatus 22 for qualifying the mask 20. At least one second two-dimensional image representation may be captured for the purpose of detecting 14 the at least one second phase difference 50.

The mask 20 can be exposed to loading 13 by use of the optical system 24, for example as shown in the exemplary embodiment of FIGS. 2A to 2E. In the exemplary embodiment according to FIGS. 2A to 2E, a partial area 28 of the mask 20 can be exposed to electromagnetic radiation, for example illumination light, as loading 13, while the remaining area is not exposed to the loading 13 by illumination light.

To detect 12 the at least one first phase difference 48 by use of the apparatus 22 for qualifying the mask 20, it is possible, for example prior to loading 13, to capture a series of first two-dimensional image representations of the mask 20 in different focal planes. A first three-dimensional image can be created from the series of first two-dimensional image representations. The first phase difference 48 can be calculated from the first three-dimensional image by use of the evaluation and control device 26.

To detect 14 the at least one second phase difference 50, it is possible, by use of the apparatus 22 for qualifying the mask 20, to capture a series of second two-dimensional image representations of the mask 20 in different focal planes. A second three-dimensional image can be created from the series of second two-dimensional image representations. The second phase difference 50 can be calculated from the second three-dimensional image by use of the evaluation and control device 26.

A two-dimensional distribution 52 of a plurality of first phase differences 48 can be determined from the series of first two-dimensional image representations of the mask 20. Such a two-dimensional distribution 52 of a plurality of first phase differences 48 is depicted in FIG. 2C in exemplary fashion. By way of example, the mask 20 can be subdivided into a grid of pixels, with at least one first phase difference 48 and/or at least one second phase difference 50 being able to be respectively determined for each pixel. In this context, a pixel may for example have an edge length of 0.02 μm to 2 μm, preferably 0.5 μm to 1.5 μm. By way of example, the mask 20 can be subdivided into at least 2×2 pixels, preferably at least 10×10 pixels, and particularly preferably at least 20×20 pixels. By way of example, a field of view of the apparatus according to the invention may cover an area of 1×1 μm² to 100×100 μm², preferably from 5×10 μm² to 20×20 μm², in particular preferably of 8×8 μm². In this case, the field of view may specify a minimum increment during scanning.

Since the mask 20 has yet not experienced inhomogeneous loading 13 when the first two-dimensional image representations are captured, the first phase differences 48 are homogenous over the mask 20 in this example, as represented in exemplary fashion in FIG. 2C by way of the dimensionless number “5”. A two-dimensional distribution 54 of a plurality of second phase differences 50 can be determined from the series of second two-dimensional image representations of the mask 20. FIG. 2D illustrates a two-dimensional distribution 54 of a plurality of second phase differences 50, with use being made of the same grid as in the distribution 52 of a plurality of first phase differences 48. Since FIG. 2D shows phase differences after a loading 13 of the partial area 28 of the mask 20 in exemplary fashion, the differences are no longer homogenous. By way of example, smaller second phase differences 50 may arise in the region of the partial area 28 of the mask 20 when compared with the remaining part of the mask 20. The comparison 15 of the first phase difference 48 with the second phase difference 50 may comprise a determination of a difference 56 between the first phase difference 48 and the second phase difference 50 by use of the evaluation and control device 26. A difference distribution 57 between the first phase difference 48 and the second phase difference 50 can be determined by use of the evaluation and control device 26 from the two-dimensional distribution 52 of a plurality of first phase differences 48 and the two-dimensional distribution 54 of a plurality of second phase differences 50. Such a difference distribution 57 between the first phase difference 48 and the second phase difference 50 is depicted in FIG. 2E by way of example. While the partial area 28 of the mask 20 has differences 56 between the first phase differences 48 and the second phase differences 50, the differences 56 in the remaining part of the mask 20 can be vanishingly small. The differences between the partial area 28 of the mask 20 and the remainder of the mask 20 may for example depend on a type of absorber structure 62 and/or the morphology of the absorber structure 62 and/or reflector structure 68, for example on the height of the absorber structure 62.

A cause for the difference 56 can be determined by use of the evaluation and control device 26 from the difference 56 between the first phase difference 48 and the second phase difference 50. The cause can be selected from a group comprising an input of energy into the mask 20, an application of electromagnetic radiation to at least a partial area 28 of the mask 20 during at least one time interval 30, an input of heat into the mask 20, a storage time 31 of the mask 20 in the device 32 for storing the mask 20, a storage time 31 in the apparatus 22 for qualifying a mask 20, a storage time 31 of the mask 20 in vacuo, an application of at least one gas to the mask 20, a contamination of the mask 20, an application of a particle beam to the mask 20, and a repair process on the mask 20.

For example, whether the detected effects are reversible or irreversible effects can be determined by use of the method according to the disclosure, for example by multiple implementations of at least a part of the method according to the disclosure. By use of the method according to the disclosure, it is possible to determine whether the loading 13 has led to an irreversible destruction of a part of the mask 20, for example of the multilayer structure and/or the absorber structure 62. By way of example, whether there were local elevations in the temperature 33, for example to above 100° C., in particular to above 400° C., can be determined by use of the method according to the disclosure. An elevation to above 400° C. can be linked with an irreversible destruction of a part of the mask 20.

In the exemplary embodiment according to FIGS. 2A to 2E, it is for example possible to deduce by way of the evaluation and control device 26 that the underlying cause is that the partial area 28 of the mask 20 was exposed to a loading 13, for example an application of electromagnetic radiation, while another partial area of the mask 20 was not exposed to any, or only exposed to a little, loading 13.

By way of example, the cause being a storage in vacuo can be deduced from an occurrence of small differences 56 between the first phase difference 48 and the second phase difference 50. Causes for jumps within the scope of a storage in vacuo can for example be vacuum adaption effects, especially relaxation processes and/or stress effects and/or outgassing. In this context, a small difference 56 between the first phase difference 48 and the second phase difference 50 can be understood to mean for example a difference 56 of no more than 75% of a saturation difference, preferably of no more than 50% of a saturation difference, and particularly preferably of no more than 10% of a saturation difference. A saturation difference can be understood to mean a difference 56 between the first difference 48 prior to the first loading 13 and a phase difference upon saturation of the loading 13. The cause being a loading procedure of the mask 20 into a vacuum chamber can alternatively or additionally be deduced in the case of an occurrence of small differences 56 between the first phase difference 48 and the second phase difference 50.

By way of example, a dwell time of the mask 20 in vacuo can be deduced from the level of a difference 56 between the first phase difference 48 and the second phase difference 50. The greater the difference 56 between the first phase difference 48 and the second phase difference 50, the greater the loading 13 by the time in vacuo may have been.

By way of example, detecting at least two differences 56 between the first phase difference 48 and the second phase difference 50 at an interval of at least one month makes it possible to deduce a contamination of the mask 20 and/or changes in storage conditions over time if a change is present.

In the case of a particularly large difference 56 between the first phase difference 48 and the second phase difference 50 in comparison with a saturation difference, it is possible to deduce an application of EUV light, especially in the case of short time durations between the detection of the phase differences, in particular after less than one week, since the time for contamination of the mask 20 and/or storage effects tend not to be expected for time intervals of less than one week. By way of example, a particularly large difference 56 can be a difference 56 between the first phase difference 48 and the second phase difference 50 of at least 80% of the saturation difference.

By way of example, the effects of temperature changes can be rectified by a calibration by use of the method according to the disclosure. By way of example, a difference 56 between the first phase difference 48 and the second phase difference 50, which is to be expected as a result of storage in vacuo, can be determined, especially for a plurality of storage times. A calibration can be implemented as a result. The expected difference 56 can be used as a basis in further measurements with the same mask 20 or with structurally identical masks. This can improve reproducibility. By use of such a calibration, it is possible for example to increase a reproducibility in respect of a time with the same mask 20 and the same apparatus 22 and/or between structurally identical masks and/or structurally identical apparatuses 22.

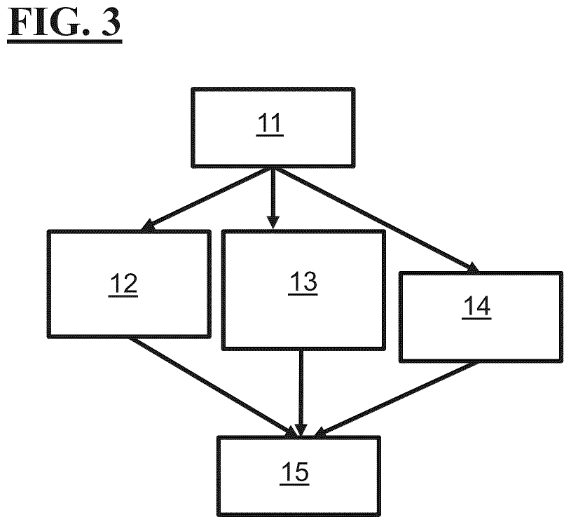

FIG. 3 shows an exemplary embodiment of a method according to the disclosure, in which the detection 12 of the at least one first phase difference 48, the loading 13 of the mask 20, and the detection 14 of the at least one second phase difference 50 at least partially overlap in time. In the exemplary embodiment according to FIG. 3, the loading 13 starts simultaneously with the detection 12 of the at least one first phase difference 48. The detection 14 of the at least one second phase difference 50 starts before the detection 12 of the at least one first phase difference 48 has been completed. By way of example, the loading 13 can at least partially endure during the detection 14 of the at least one second phase difference 50. By way of example, the detection 14 of the at least one second phase difference 50 can start while the evaluation and control device 26 calculates the at least one first phase difference 48 from measurement data. The method in accordance with the exemplary embodiment according to FIG. 3 starts with the provision 11 of the apparatus 22 according to the disclosure and for example ends following the implementation of the comparison 15. As an alternative thereto, the detection 12 of the at least one first phase difference 48 and/or the loading 13 of the mask 20 and/or the detection 14 of the at least one second phase difference 50 can be repeated one or more times prior to this.

One or more of the method steps may be repeated in all exemplary embodiments of the method according to the disclosure. By way of example, one or more steps of the method can be repeated at one location on the mask 20. As an alternative or in addition, one or more of the steps can be repeated at different locations on the mask 20.

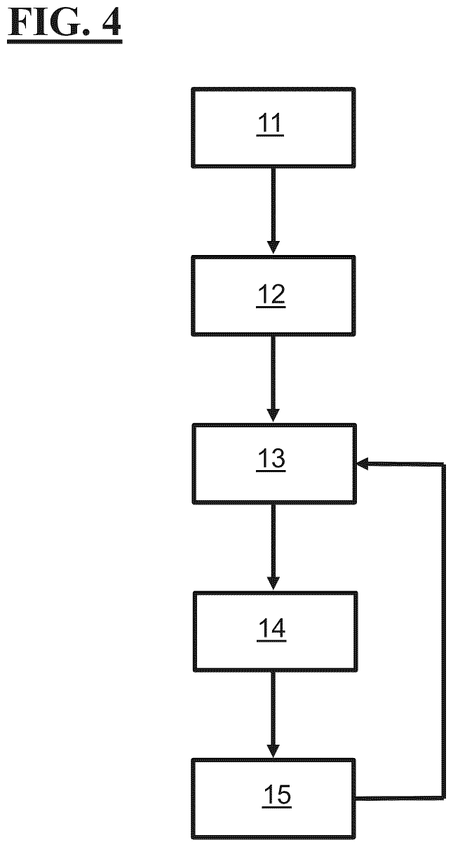

In the exemplary embodiment of a method according to the disclosure and according to FIG. 4, the provision 11 of the apparatus 22 and the detection 12 of the at least one first phase difference 48 are followed by multiple instances in the specified sequence of the loading 13 of the mask 20, the detection 14 of the at least one second phase difference 50, and the implementation of the comparison 15. The step may overlap, at least in parts.

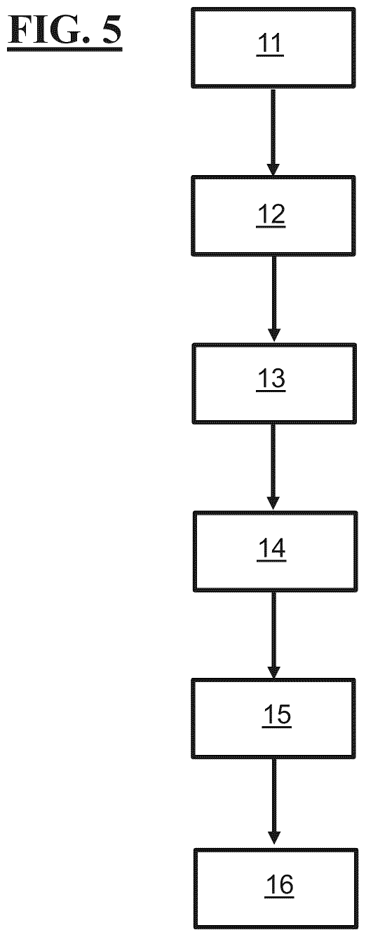

The exemplary embodiment according to FIG. 5 shows a method according to the disclosure, in which the provision 11 of the apparatus 22 is followed by the detection 12 of the at least one first phase difference 48, the loading 13 of the mask 20, the detection 14 of the at least one second phase difference 50, the implementation of the comparison 15 and a sixth step 16, especially in the sequence mentioned. The steps may overlap in time, at least in part. The sixth step 16 can be for example a repair step or an output of a result of the comparison 15.

By way of example, the exemplary embodiment depicted in FIG. 6 can be designed like the exemplary embodiment depicted in FIG. 5, with the loading 13 of the mask 20, the detection 14 of the at least one second phase difference 50, and the implementation of the comparison 15 being repeated one or more times, in particular in the sequence mentioned. By way of example, the steps may overlap.

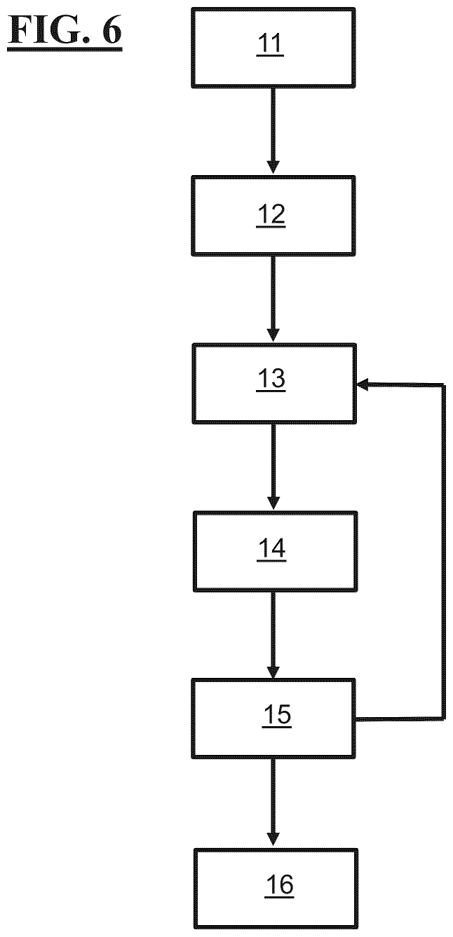

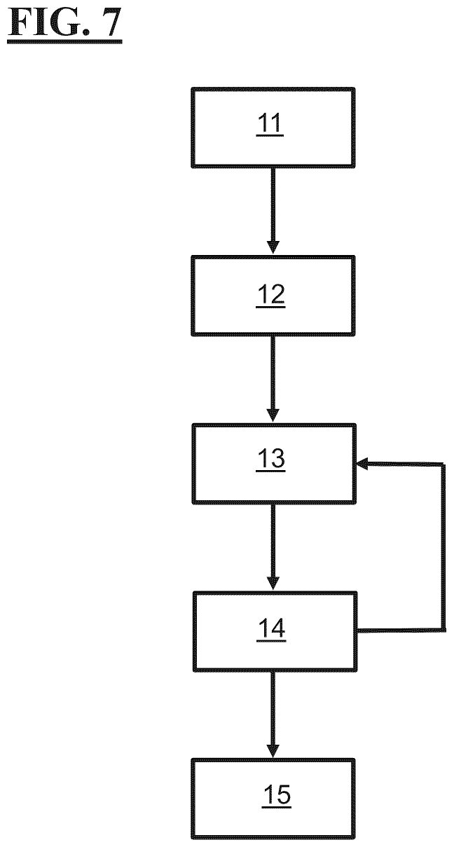

The exemplary embodiment according to FIG. 7 may be designed like the exemplary embodiment according to FIG. 1, with the loading 13 of the mask 20 and the detection 14 of the at least one second phase difference 50 being repeated one or more times.

By way of example, at least a first phase difference 48 and a second phase difference 50 may be determined for each of a plurality of points on the mask 20 arranged in raster-like fashion, for example as depicted in the exemplary embodiment according to FIGS. 2A to 2E. By way of example, at least one first phase difference 48 and one second phase difference 50 can be determined in each case for more than 5 fields of view per hour, preferably for more than 10 fields of view per hour, and particularly preferably for 15 to 18 fields of view per hour. By way of example, a plurality of first phase differences 48 can be detected simultaneously within a field of view. By way of example, a plurality of second phase differences 50 can also be detected simultaneously within a field of view.

During loading 13, the mask 20 can be at least loaded up to a threshold value 72. By way of example, the loading 13 can be up to the threshold value 72 in one method step. As an alternative thereto, loading 13 can be repeated until the threshold value 72 is exceeded, for example as depicted in FIGS. 4, 6, and 7. The threshold value 72 may be a characteristic, above which a detectable difference 56 between the first phase difference 48 and the second phase difference 50 arises by use of the method according to the invention. The threshold value 72 can be determined by use of the evaluation and control device 26.

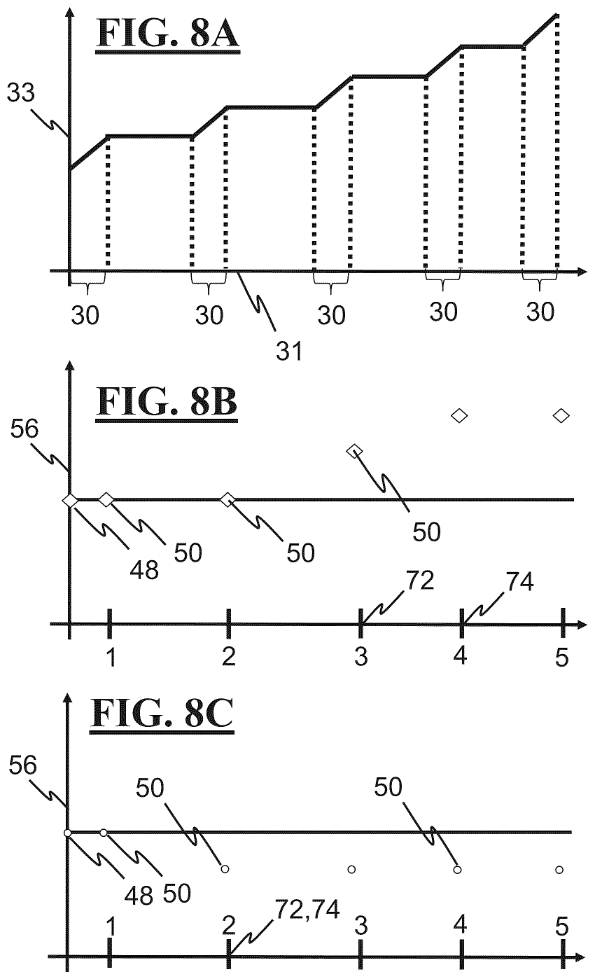

FIG. 8A shows a diagram reproducing a curve of a temperature 33 of at least a part of a mask 20 over time, for an exemplary embodiment of a method according to the disclosure. Loading 13 of the mask 20 is implemented in each of the repeating time intervals 30. The loading 13 may be connected in particular to an energy input into the mask 20. By way of example, the loading 13 may comprise loading with electromagnetic radiation and/or heating the mask 20 by a heating procedure. The loadings 13 may preferably comprise pulses of electromagnetic radiation with a duration of 1 ns to 100 ns, preferably 20 ns to 40 ns, and particularly preferably 30 ns. By way of example, an absorbed energy per pulse can be between 1 J/m² and 100 J/m², preferably between 10 J/m² and 20 J/m², and particularly preferably between 16 J/m² and 17 J/m². The temperature 33 may increase during the loadings 13. FIG. 8B shows a curve of phase differences over time for the temperature curve according to FIG. 8A, starting with the first phase difference 48 and a plurality of second phase differences 50 following this. There is no difference 56 between the first phase difference 48 and the second phase difference 50 since the threshold value 72 has not yet been exceeded by the first loading 13 during the first time interval 30. There is no difference 56 between the further second phase difference 50 and the first phase difference 48 either following the second loading 13 during the second time interval 30. A difference 56 between the further second phase difference 50 and the first phase difference 48 that is measurable by use of the method only arises after the third loading 13, which is to say after the third time interval 30. Thus, the threshold value 72 of the loading 13 was exceeded. Another difference 56 arises after the fourth loading 13. There is no further change 76 in the phase difference following the fifth loading 13. In this exemplary embodiment, a saturation value 74 of the loading 13 is attained here.

The mask 20 can be at least loaded up to a saturation value 74. The saturation value 74 can be a characteristic at which there is no further change 76 in the phase difference in the case of further loading 13. By way of example, the saturation value 74 may correspond to 1.5-times to 10-times the energy input of a usual measurement of the mask 20, preferably 3-times to 5-times the energy input, and particularly preferably 4-times the energy input of a measurement of the mask 20 without loading 13 by use of the apparatus according to the invention. By way of example, the saturation value 74 may correspond to 5-times to 50-times, preferably less than 20-times the energy input in comparison with a lithography method. The saturation value 74 can be determined by use of the evaluation and control device 26, for example after repeated loading 13 and repeated detection 14 of the second phase difference 50.

By way of example, the saturation value 74 may also be identical to the threshold value 72, for example as depicted in FIG. 8C. In the case of a pretreatment of the mask 20, there can be loading 13 up to at least the saturation value 74. Implementing a lithography method using a pretreated mask 20 allows the suppression of inaccuracies due to phase effects.

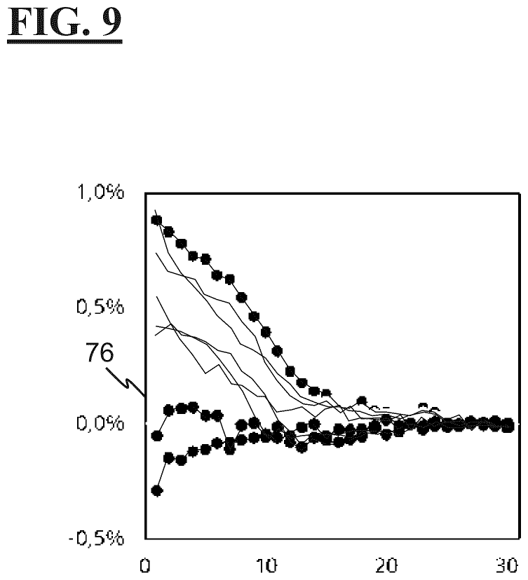

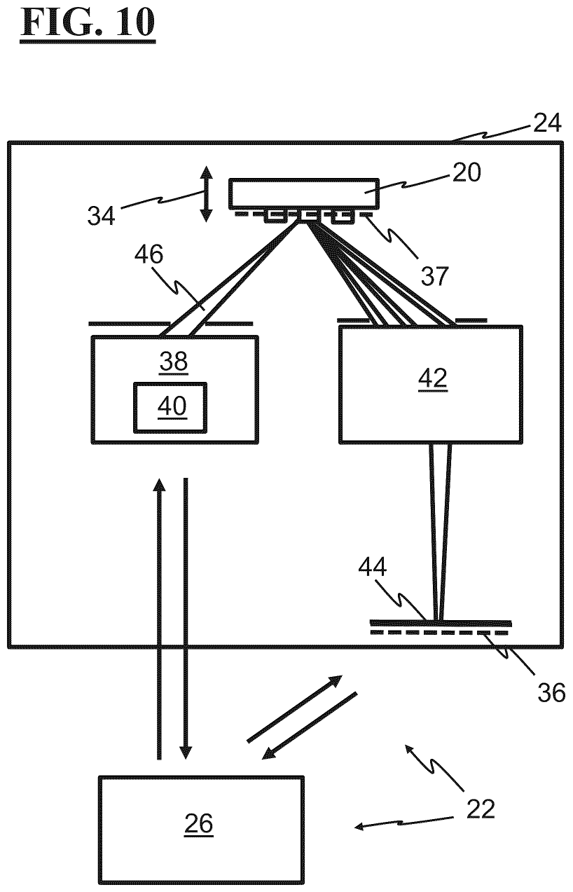

FIG. 9 shows differences 56 of second phase differences 50 from respective mean values of the five second phase differences 50 measured therebefore. The individual measurement series may be assigned to different absorber heights. The ordinate shows respective deviations from the respective mean values of the five second phase differences 50 measured therebefore, as a percentage of a difference 56 between the first phase difference 48 and a second phase difference 50 following loading 13 in accordance with the saturation value 74. The abscissa shows the number of repeated measurements of second phase differences 50. Alternatively, the abscissa could also be designed as accumulated EUV dose. For each loading 13, the difference 56 reaches a value of 0%, which is to say a saturation of the loading, at an earlier or later stage in the case of repeated and/or continuous loading 13. In this way, it is possible to show that, in particular, a saturation value 74 can be attained by use of the method according to the disclosure and that such a pretreatment can increase a reproducibility, for example by saturating effects which arise from storage in vacuo.

A rather low photon flux may be advantageous in these exemplary embodiments. In particular, a photon flux during loading 13 could be so low that a profile up to saturation can be detected and analyzed in the case of multiple detections 14 of the second phase differences 50. By way of example, curves according to FIG. 9 allow conclusions to be drawn about the thickness of the layer of a mask 20, for example about the absorber height and/or about the absorber material and/or about the existence of a protective layer and/or about a storage duration in vacuo.

Preconditioning of the mask 20 can be achieved by attaining the saturation value 74. Preferably, the light intensities when loading 13 by electromagnetic radiation in the method according to the disclosure can be higher than in the case of a lithography method. As a result, the method according to the disclosure is particularly suitable for increasing a reproducibility in a lithography method since the saturation value 74 is attained earlier in the method according to the disclosure, for example after one to 20, preferably one to 10 detections 14 of a second phase difference 50. As a result, defects in a lithography method that can be traced back to the mask 20 can be reduced.

The evaluation and control device 26 can include one or more computers that include one or more data processors configured to execute one or more computer programs that include a plurality of instructions according to the principles described in this document. The one or more computers can include one or more data processors for processing data, one or more storage devices for storing data, such as one or more databases, and/or one or more computer programs including instructions that when executed by the computing unit cause the computing unit to carry out the processes. The one or more computers can include one or more input devices, such as a keyboard, a mouse, a touchpad, and/or a voice command input module, and one or more output devices, such as a display, and/or an audio speaker. In some implementations, the one or more computers can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

While the disclosure has been described in connection with certain examples, it is to be understood that the disclosure is not to be limited to the disclosed examples but, on the contrary, is intended to cover various modifications and equivalent arrangements included within the scope of the appended claims, which scope is to be accorded the broadest interpretation so as to encompass all such modifications and equivalent structures as is permitted under the law.

### LIST OF REFERENCE SIGNS

11 Provision of an apparatus
12 Detecting at least one first phase difference
13 Loading the mask
14 Detecting at least one second phase difference
15 Implementing a comparison
16 Sixth step
20 Mask
22 Apparatus
24 Optical system
26 Evaluation and control device
28 Partial area of the mask
30 Time interval
31 Storage time
32 Device for storing the mask
33 Temperature of the mask
34 Drive
36 Image plane
37 Object plane
38 Illumination unit
40 EUV light source
42 Imaging unit
44 Detection unit
46 Light
48 First phase difference
50 Second phase difference
52 Two-dimensional distribution of a plurality of first phase differences
54 Two-dimensional distribution of a plurality of second phase differences
56 Difference between the first phase difference and the second phase difference
57 Difference distribution
58 First absorber layer
60 Second absorber layer
62 Absorber structure
64 Absorber light beam
66 Reflector light beam
68 Reflector structure
72 Threshold value
74 Saturation value
76 Change in the difference between the first phase difference and the second phase difference

What is claimed is:

1. A method for qualifying a mask for use in lithography, the method including the following steps:
providing an apparatus for qualifying a mask, the apparatus comprising an optical system and an evaluation and control device;
detecting at least one first phase difference of light at the mask by use of the optical system and the evaluation and control device;
loading the mask;
detecting at least one second phase difference of light at the mask by use of the optical system and the evaluation and control device; and
implementing a comparison of the first phase difference with the second phase difference by use of the evaluation and control device.

2. The method of claim 1, wherein the loading is selected from a group comprising an input of energy into the mask, an application of electromagnetic radiation to at least a partial area of the mask during at least one time interval, an input of heat into the mask, a storage time of the mask in the device for storing the mask, a storage time in the apparatus for qualifying a mask, a storage time of the mask in vacuo, an application of at least one gas to the mask, a contamination of the mask, an application of a particle beam to the mask, and a repair process on the mask.

3. The method of claim 1, wherein the mask comprises an absorber structure and a reflector structure, with at least one phase difference between an absorber light beam reflected at the absorber structure and a reflector light beam reflected at the reflector structure being detected in each case within the scope of the detection of the at least one first phase difference and the at least one second phase difference.

4. The method of claim 1, wherein one or more of the steps are repeated.

5. The method of claim 1, wherein the mask is loaded up to at least one threshold value, the threshold value being a characteristic above which there is a difference between the first phase difference and the second phase difference.

6. The method of claim 5, wherein the threshold value is determined by use of the evaluation and control device.

7. The method of claim 1, wherein the mask is loaded up to at least one saturation value, the saturation value being a characteristic at which there is no further change in the phase difference in the case of further loading.

8. The method of claim 7, wherein the saturation value is determined by use of the evaluation and control device.

9. The method of claim 1, wherein the mask is exposed to the loading by use of the optical system.

10. The method of claim 1, wherein the mask is exposed to the loading by use of a device for storing the mask.

11. The method of claim 1, wherein the comparison of the first phase difference with the second phase difference comprises a determination of a difference between the first phase difference and the second phase difference by use of the evaluation and control device.

12. The method of claim 11, wherein a cause for the difference is determined by use of the evaluation and control device from the difference between the first phase difference and the second phase difference.

13. The method of claim 12, wherein the cause is selected from a group comprising an input of energy into the mask, an application of electromagnetic radiation to at least a partial area of the mask during at least one time interval, an input of heat into the mask, a storage time of the mask in the device for storing the mask, a storage time in the apparatus for qualifying a mask, a storage time of the mask in vacuo, an application of at least one gas to the mask, a contamination of the mask, an application of a particle beam to the mask, and a repair process on the mask.

14. The method of claim 1, wherein at least one first two-dimensional image representation is captured for detecting the at least one first phase difference by use of the apparatus for qualifying the mask, with at least one second two-dimensional image representation being captured for detecting the at least one second phase difference.

15. The method of claim 1, wherein a series of first two-dimensional image representations of the mask in different focal planes is captured for the purposes of detecting the at least one first phase difference by use of the apparatus for qualifying the mask, with a first three-dimensional image being created from the series of first two-dimensional image representations, with the first phase difference being calculated from the first three-dimensional image by use of the evaluation and control device, with a series of second two-dimensional image representations of the mask in different focal planes being captured for the purposes of detecting the at least one second phase difference by use of the apparatus for qualifying the mask, with a second three-dimensional image being created from the series of second two-dimensional image representations, and with the second phase difference being calculated from the second three-dimensional image by use of the evaluation and control device.

16. The method of claim 15, wherein a two-dimensional distribution of a plurality of first phase differences is determined from the series of first two-dimensional image representations of the mask, with a two-dimensional distribution of a plurality of second phase differences being determined from the series of second two-dimensional image representations of the mask, and with a difference distribution between the first phase difference and the second phase difference being determined by use of the evaluation and control device from the two-dimensional distribution of a plurality of first phase differences and the two-dimensional distribution of a plurality of second phase differences.

17. The method of claim 1, wherein a control signal is generated for the apparatus for qualifying the mask, the control signal being created by means of the comparison.

18. The method of claim 1, wherein the light has a wavelength between 1 nm and 250 nm, in particular between 10 nm and 100 nm, and preferably between 13 nm and 14 nm.

19. The method of claim 1, wherein the light is pulsed light with a pulse duration of between 0.1 femtoseconds and 400 nanoseconds, preferably between 50 femtoseconds and 100 nanoseconds, and particularly preferably between 25 nanoseconds and 35 nanoseconds.

20. An apparatus for qualifying a mask for use in lithography, the apparatus comprising an optical system and an evaluation and control device, with the optical system and the evaluation and control device being configured to detect a first phase difference of light at the mask, with the apparatus being configured to expose the mask to loading, with the optical system and the evaluation and control device being configured to detect a second phase difference of light at the mask after the loading, and with the evaluation and control device being configured to implement a comparison of the first phase difference with the second phase difference.
